(19) United States
(12) Patent Application Publication
(10) Pub. No.: US 2002/0171441 A1
(43) Pub. Date: Nov. 21, 2002

(54) Method and apparatus for accelerated life testing of a solar cell

(75) Inventor: Upali Nissanka Jayamaha, Toledo, OH (US)

Correspondence Address: Harold H. Fox, FISH & RICHARDSON P.C., 1425 k Street, N.W., 11Th Floor, Washington, DC, 20005-3500, US

(73) Assignee: First Solar LLC, Perrysburg, OH (US)

(21) Appl. No.: 09/859,717

(22) Filed: May 17, 2001

(51) Int. Cl. G01R 31/302

(52) U.S. Cl. 324/752

(57) ABSTRACT

A method of accelerated life testing of a solar cell includes directing a high-intensity diode laser light through at least one lens onto a small area of the solar cell continuously for a predetermined period of time to simulate long-term sun exposure. Performance of the solar cell is measured before and after exposure to the laser light so that life expectancy unless long-term sun exposure may be determined.

### BACKGROUND OF THE INVENTION

1. Field of the Invention

The present invention relates to a method of accelerated life testing of a solar cell in which a high-intensity diode laser light is focused onto a small area of a solar cell for a predetermined period of time to simulate long-term sun exposure, and the performance of the cell is measured to determine life expectancy.

2. Background Art

Previously, the only known way in which solar cells could undergo accelerated life testing would have been under high-intensity light from focused gas laser beams or Xenon discharge light. However, high power gas lasers and Xenon lights are very expensive. Also, Xenon discharge light creates a significant amount of heat due to its large infrared light content. This causes extensive heat build-up in a solar cell to which the light is directed. Accordingly, it is inefficient. The Xenon light is also difficult to focus.

It is desirable to provide a method and apparatus for accelerated life testing of a solar cell in a manner which is relatively inexpensive and efficient in comparison with the methods described above.

### SUMMARY OF THE INVENTION

The present invention provides an improved method and apparatus for accelerated life testing of solar cells in which a high-intensity diode laser light is focused onto a small area of a solar cell for a predetermined period of time to simulate long-term sun exposure, and performance of the solar cell is measured to determine life expectancy.

Preferably, the laser light is directed through an aspherical lens to form a rectangular parallel beam, and then the rectangular parallel beam is directed through a cylindrical lens to evenly focus the beam onto the small area of the solar cell, which is preferably less than 1 mm².

The diode laser light preferably has a wavelength between 500 nm and 850 nm, and the light is directed onto the small area of the solar cell for approximately 24 hours. The performance of the solar cell may be measured before and after the illumination of the small area, and the performance before and after would be compared to extrapolate life expectancy. Also, voltage and current may be measured across the solar cell during the illumination, and the diode laser light may be cycled “on” and “off” to simulate daytime and nighttime exposure.

This testing method may comprise cutting the small area off a larger solar cell prior to illumination of the small area, or the laser light may be directed onto a sufficiently small area of the solar cell such that the performance of the solar cell is not significantly compromised by the test.

The solar cell includes a tin oxide coated glass substrate which acts as a heat sink to reduce heat build-up during the illumination.

Accordingly, an object of the invention is to provide a method and apparatus for accelerated life testing of solar cells in an inexpensive and efficient manner.

The above object and other objects, features, and advantages of the present invention are readily apparent from the following detailed description of the preferred embodiment when taken in connection with the accompanying drawings.

### BRIEF DESCRIPTION OF THE DRAWINGS

FIG. 1 shows a schematic side view of a testing apparatus in accordance with the invention; and

FIG. 2 shows a graphical illustration of solar cell temperature vs. laser light intensity in accordance with the invention.

### DETAILED DESCRIPTION OF THE PREFERRED EMBODIMENT

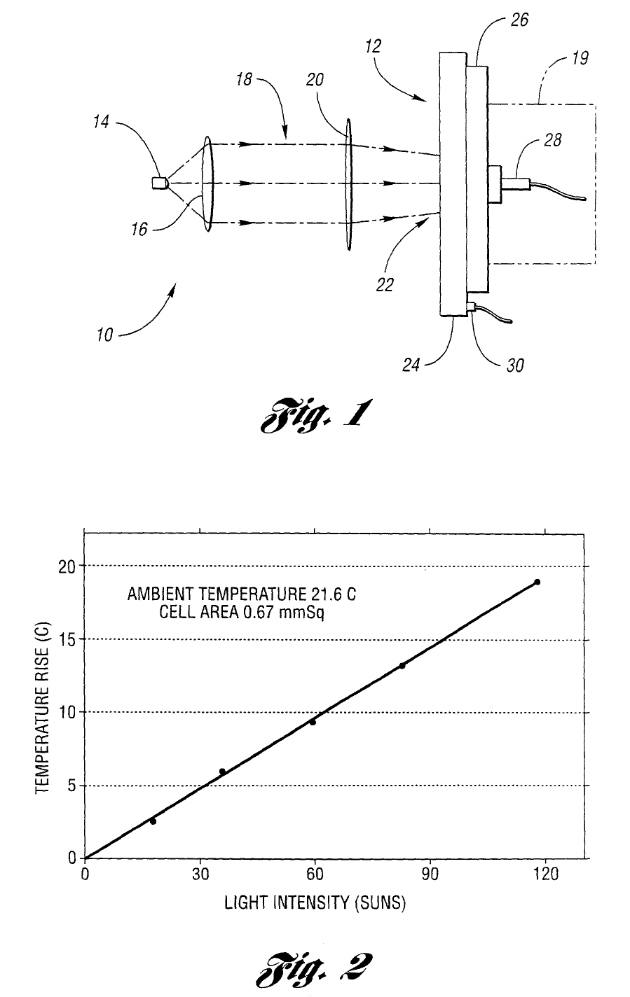

FIG. 1 shows an apparatus 10 for accelerated life testing of a solar cell 12 in accordance with the invention. The apparatus 10 includes a high intensity diode laser 14 which directs diode laser light through an aspherical lens 16 to form a rectangular parallel beam 18. The rectangular parallel beam 18 is directed through a cylindrical lens 20 so that it is focused onto the solar cell 12, which is held by the test fixture 19.

Increasing the intensity of illumination of the solar cell 12 accelerates the light-induced degradation of the solar cell. This invention makes use of newly developed diode lasers (670-810 nm wavelength) as the high-intensity light source. Diode lasers, also known as semiconductor lasers, are small and can be mass-produced relatively inexpensively. They are typically highly reliable and durable. Their principle application is as the light source in optical fiber communications, compact disc players, and supermarket bar code readers. They are also used for eye surgery.

By selecting appropriate diode lasers and focused spot sizes, it is possible to subject the cells to very high-intensity with very little heating. With this scheme, the cost of testing a cell under an effective illumination as high as 1,000 suns is only about $350.00. It would cost more than ten times as much to get the same light intensity with a Xenon discharge light or gas laser beam, as described in the Background Art section above, in comparison to the new diode lasers.

In a preferred embodiment, the diode laser 14 is model number LD-808-500G, which is available from Lasermate Corporation of Walnut, Calif.

As shown in FIG. 1, after passing through the cylindrical lens 20, the laser light is focused evenly onto the micro-sized area 22 of the solar cell 12. The micro-sized area is preferably less than 1 mm². As shown, the solar cell 12 comprises a “glass+TCO” layer 24. The TCO layer may be tin oxide, for example. The solar cell 12 also includes a cadmium sulfide/cadmium telluride layer 26. The solar cell 12 is held in a fixture (not shown) for x-y positioning, and first and second electrical contacts 28,30 are provided for measuring current and voltage across the solar cell 12.

Using the diode laser described above, the solar cell 12 is exposed to laser light at about 808 nm for approximately one day, and the performance of the solar cell 12 is measured before and after the laser light exposure. During the laser light exposure, the solar cell could be under open circuit, short circuit, or resistive load. The voltage and current during the laser light exposure is also measured to get additional information on degradation. Furthermore, the laser could also be turned “on” and “off” periodically to mimic the day/night light exposure. A significant advantage of this scheme is that solar cell heating is minimal because the substrate acts as an infinite heat sink for the heat generated in the micro-sized solar cell.

FIG. 2 shows the temperature rise measured using a micro-sized thermocouple during the light soak as a function of laser light intensity. It can be seen that even under intensity as high as 120 suns, the temperature rise is only about 18° C. If needed, the cells under laser light soak could be heated to a higher temperature to study the effects of temperature by blowing hot air onto the cell.

The voltage and current across the solar cell may be measured during the laser light exposure. The laser light preferably has a wavelength between approximately 500 nm and 850 nm. Under one sun of illumination, only approximately 30% of the light is active in the solar cell. However, at 808 nm wavelength, almost all of the light is active.

In performing the test, the small area of the solar cell may be cut away from a larger solar cell prior to illumination to facilitate handling of the small area of the solar cell for testing. Alternatively, the diode laser light may be exposed to a sufficiently small area of the solar cell such that the performance of the overall solar cell is not significantly compromised by the test. Also, it is contemplated that this testing system and method could be used in a manufacturing process and every solar cell could be tested on such a small area so that the entire solar cell is not compromised.

While the best mode for carrying out the invention has been described in detail, those familiar with the art to which this invention relates will recognize various alternative designs and embodiments for practicing the invention within the scope of the appended claims.

What is claimed is:

1. A method of accelerated life testing of a solar cell comprising:
directing a high-intensity diode laser light through at least one lens onto a small area of the solar cell for a predetermined period of time to simulate long-term sun exposure; and
measuring performance of the solar cell after said predetermined period of time expires.

2. The method of claim 1, wherein said directing step comprises directing the laser light through an aspherical lens to form a rectangular parallel beam, and then directing the rectangular parallel beam through a cylindrical lens to evenly focus the beam onto the small area of the solar cell.

3. The method of claim 1, wherein said small area is less than 1 mm².

4. The method of claim 1, wherein said diode laser light has a wavelength between approximately 500 nm and 850 nm.

5. The method of claim 1, wherein said predetermined period of time comprises approximately 24 hours.

6. The method of claim 1, further comprising measuring performance of the solar cell prior to said directing step, and comparing this measured performance with the measured performance after the period of time expires.

7. The method of claim 1, further comprising measuring voltage and current across the solar cell during said step of directing a diode laser light onto the small area.

8. The method of claim 1, further comprising cycling the diode laser light on and off to simulate daytime and nighttime conditions.

9. The method of claim 1, wherein the solar cell comprises a tin oxide coated glass substrate.

10. The method of claim 1, further comprising cutting the small area off a larger solar cell prior to said directing step.

11. The method of claim 1, wherein said small area of the solar cell is sufficiently small such that the performance of the solar cell is not significantly compromised by the directing step.

12. An apparatus for accelerated testing of a solar cell comprising:
a testing fixture for holding a solar cell;
a diode laser positioned to direct laser light toward the solar cell;
an aspherical lens positioned to receive said laser light and to form a rectangular parallel beam of the laser light; and
a cylindrical lens positioned to receive said rectangular parallel beam and focus the beam onto a small area of the solar cell.

13. The apparatus of claim 12, wherein the small area is less than 1 mm².

14. The apparatus of claim 12, wherein said diode laser light has a wavelength between approximately 500 nm and 850 nm.

15. The apparatus of claim 12, wherein the solar cell comprises a tin oxide coated glass substrate which acts as a heat sink to minimize heat build-up in the solar cell during testing.

16. A method of accelerated life testing of a solar cell comprising:
directing a high-intensity diode laser light through an aspherical lens to form a rectangular parallel beam, and then directing the rectangular parallel beam through a cylindrical lens to evenly focus the beam onto a small area of the solar cell for a predetermined period of time; and
measuring performance of the solar cell after said predetermined period of time expires.

17. The method of claim 16, wherein said directing step is performed on all panels manufactured in a solar cell manufacturing process, and the small area is sufficiently small such that the performance of each solar cell is not significantly compromised by the directing step.
